(19) United States
(12) Patent Application Publication
(10) Pub. No.: US 2009/0001346 A1
(43) Pub. Date: Jan. 1, 2009

(54) Non-Volatile Polymer Bistability Memory Device

(75) Inventors: Tae-whan Kim, Seoul (KR); Young-ho Kim, Seoul (KR); Jae-ho Kim, Seoul (KR); Jae-hum Jung, Seoul (KR); Young-bae Yoon, Gunsan (KR); Sung-keun Lim, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignees: SAMSUNG ELECTRONICS CO., LTD., Gyeonggi-do (KR); INDUSTRY-UNIVERSITY COOPERATION FOUNDATION HANYANG UNIVERSITY, Seoul (KR)

(21) Appl. No.: 11/815,331

(22) PCT Filed: Sep. 26, 2005
(86) PCT No.: PCT/KR2005/003194

§ 371 Date: Apr. 1, 2008

(30) Foreign Application Priority Data
Feb. 4, 2005 (KR) 10-2005-0010809

(51) Int. Cl. H01L 47/00; H01L 21/3205

(52) U.S. Cl. 257/4; 438/593; 257/E45.002

(57) ABSTRACT

The present invention relates to non-volatile memory device utilizing multi-layered self-assembled Ni1-xFex nanocrystalline arrays embedded in a polymer thin film without source and drain regions and the fabrication method thereof. It is possible to fabricate nano-crystallines more simply than hitherto method according to the present invention. More particularly, it is possible to control size and density of nano-crystallines without agglomeration of the crystallines since the crystallines, which have uniform distribution, are besieged to polymer layer. Furthermore, the present invention provides the non-volatile bistable memory device having chemical and electrical stability of higher efficiency and lower cost than conventional flash memory devices with a nano floating gate. Also, source and drain region is unnecessary in the device of the present invention, it can reduce the throughput time and cost.

### FIELD OF THE INVENTION

The present invention relates to a non-volatile polymer bistability memory device with a nano-scale floating gate and a fabrication method thereof, more particularly, to a non-volatile memory device utilizing multi-layered self-assembled Ni₁₋ₓFeₓ nano-crystalline arrays embedded in a polymer thin film, so that it requires no source and drain regions and exhibits high efficiency and cost effectiveness.

### BACKGROUND OF THE INVENTION

Recently, three-dimensionally confined nano-crystallines embedded in a dielectric layer have been investigated extensively for the applications in non-volatile memory devices with nano-scale floating gates. Several researches relate to formation of Si nano-particles embedded in a SiO₂ layer using scanning prove, e-beam, and X-ray methods (S. Huang, S. Banerjee, R. T. Tung, and S. Oda, J. Appl. Phys. 94, 7261 (2003), S. J. Lee, Y. S. Shim, H. Y. Cho, D. Y Kim, T. W. Kim, and K. L. Wang, Jpn. J. Appl. Phys. 42, 7180 (2003), S. Huang, S. Banerjee, R. T. Tung, and S. Oda, J. Appl. Phys. 93, 576 (2003)).

However, a study on multi-layered self-assembling nano-particle arrays embedded in an alternative dielectric layer using simple techniques has not been yet reported.

Recently, there is a large demand for new materials replacing the SiO₂ layer which has been mainly used as an insulating material since inorganic materials have shown many defects such as complicate fabrication process and high fabrication cost, in spite of their technological and commercial advantages.

Polyimide as an organic insulating material is developed to replace conventional inorganic insulating materials. Since polyimide exhibits unique thermal, mechanical, and dielectric properties, it has been widely used in a variety of ultra-precision electronic industries including insulating intermediate layers of integrated circuits and high density interconnecting packages. Particularly, it is known that a dielectric constant of polyimide is lower than those of the conventional inorganic materials.

The conventional flash memory device generally comprises a drain region and a source region space-apart from each other and positioned on a silicon substrate, a thin film tunnel oxide layer formed in a channel region between the drain region and the source region, a floating gate made of polysilicon formed thereon, an inter-electrode insulating layer formed on the floating gate electrode, and a control gate electrode receiving a particular amount of voltage.

However, it has been recently found that in the fabrication of a memory device, locating a ultra thin film metal layer between two organic layers results in excellent electric bistability, and from the observation, the studies on bistable memory device without source and drain regions have been performed.

But the methods of forming a nano-crystalline layer simply and controlling the density, the grain size, and the thickness of the layer consisting of nano-crystalline in the fabrication of the bistability memory device have not yet disclosed.

Therefore, it has been demanded to develop techniques to form bistable complexes between organic insulating layers and just the technique to simply control the size or density of particles of nano-crystallines forming metal layers in the fabrication of the non-volatile bistable memory device, which is next-generation nonvolatile memory device.

### DETAILED DESCRIPTION OF THE INVENTION

To solve the described technical problems, an aspect of the present invention provides a bistable memory device of high efficiency and low-cost which requires no source and drain regions by simply forming Ni₁₋ₓFeₓ nano-crystallines within a polymer through simple deposition and heat treatment, so that the efficiency becomes high and the fabrication cost becomes low, and a fabrication method thereof.

A bistable memory device of the present invention allows a conversion at low resistance (impedence) state and a high resistance state by supplying a suitable electric voltage. The bistable memory device of the present invention has a first electrode on one side of a bistable complex and a second electrode on the other side of the bistable complex. Within the bistable complex, one or more distinguished layers composed of a conductive metal or a conductive oxide of nano-particles are positioned. Also a polymer material having low conductivity is used as an insulating material in the bistable complex.

The bistable memory device of the present invention comprises a semiconductor substrate; an insulating layer formed on the semiconductor substrate; a first electrode formed on the insulating layer; a bistable complex composed of multi-layered Ni₁₋ₓFeₓ nano-crystalline arrays in a polymer thin film formed on the first electrode; and a second electrode on the bistable complex, which is formed separated electrically by the polymer thin film. The bistable complex composed of Ni₁₋ₓFeₓ nano-crystallines in the polymer thin film is formed with 2 or more layers.

Preferably, the polymer thin film is a polyimide thin film.

For the electrode, conventional materials such as aluminum and copper are preferable and Indium tin oxide (ITO), Indium oxide, other suitable metal oxides, and conductive polymers such as PEDOT and doped polyanaline may be also used.

Also, the fabrication method of a flash memory device of the present invention comprises the steps of:

forming an insulating layer on a semiconductor substrate;

forming a first electrode layer on the insulating layer;

forming a bistable complex composed of multi-layered Ni₁₋ₓFeₓ nanocrystalline arrays in a polymer thin film on the first electrode; and

forming a second electrode layer on the bistable complex.

Preferably, the step of forming the bistable complex comprises:

a) spin-coating a polymer solution obtained by dissolving an acidic precursor containing a monomer of the insulating polymer into a solvent on the coated metal (first electrode) and removing the solvent from the coated acidic precursor;

b) coating Ni₁₋ₓFeₓ on the resulting polymer layer;

c) repeating a) and b) steps at least once; and

d) spin-coating a polymer solution obtained by dissolving an acidic precursor containing a monomer of the insulating polymer into a solvent and heating the polymer to effect cross-linking in the coated acidic precursor.

Concerning the acidic precursor containing a monomer of the insulating polymer, the acidic precursor containing a carboxyl group may be preferable.

In the Ni₁₋ₓFeₓ, the range of x, 0<x<0.5, is more preferable.

As to a coating method of Ni₁₋ₓFeₓ, any known method suitable for coating metal may be used including deposition, sputtering and the like.

For a solvent of the present invention, one or more can be selected from the group consisting of N-methyl-2-pyrrolidone (NMP), water, N-dimethylacetamide and diglyme depending on the type of a precursor of the insulating material.

More preferably, the step of forming the bistable complex comprises:

1) depositing a metal electrode on a semiconductor substrate on which the insulating layer is deposited;

2) spin-coating a polyamic acid of biphenyltetracaboxylic dianhydride-p-phenylenediamine (BPDA-PDA) type using N-methyl-2-pyrrolidone (NMP) as a solvent;

3) coating a Ni₁₋ₓFeₓ layer with a thickness of 1-30 nm on the resulting polyimide layer after removing the solvent; and

4) repeating 2) and 3) steps at least once and heating at 300-400° C. for about 1 hour to harden it.

According to the present invention, it is possible to form the bistable complex wherein multi-layered Ni₁₋ₓFeₓ nano-crystalline arrays of high density dispersed in the polyimide thin film are formed. Also, it is easy to control the overall characteristics of the device since it is possible to control the size and density of the nano-crystallines by changing a initial coating thickness of Ni₁₋ₓFeₓ, a mixture ratio of the solvent and the precursor, and a hardening condition. Because it is unnecessary to form source and drain regions in fabricating the non-volatile memory device of the present invention, the volume of the whole device is reduced and the fabrication process is simplified.

Since voltage-current characteristics according to the bistable memory device of the present invention shows hysteresis manner electrically as illustrated in FIG. 1, an operation of writing and reading is possible. The description of an operation mechanism of the non-volatile memory device according to the present invention is as follows.

FIG. 2 is a schematic diagram illustrating the energy band of the non-volatile bistable memory device when voltage is not supplied to the device.

When supplying a voltage in a forward direction (V_{TH}) to the non-volatile memory device of the present invention to ‘write’ thereon, electrons in a Ni₁₋ₓFeₓ layer are tunneling into a thin polyimide layer opposite direction to an electric field, resulting in accumulation of the holes having positive charges in the Ni₁₋ₓFeₓ layer and leaving negative charges in the polyimide layer adjacent to the Ni₁₋ₓFeₓ layer. Due to the doping effect in the polyimide layer, it is possible to reduce the overall resistance and make current flow fluently, and then ‘write’ (refer to FIG. 3). Although the supplied voltage is removed, it is possible to ‘write’ on the flash memory device of the present invention in a non-volatile manner since the polyimide layer functions as an insulating layer in-between the Ni₁₋ₓFeₓ layers and blocks re-association of charges which results in a paramagnetic state (refer to FIG. 4).

When supplying an erase voltage in a backward direction (Vₑᵣₐₑ) to the non-volatile memory device of the present invention to perform ‘delete’, electrons accumulated in the Ni₁₋ₓFeₓ layer are tunneling into a thin polyimide layer opposite direction to in ‘write’. It neutralizes polarity of the entire Ni₁₋ₓFeₓ layer and the doping effect of the polyimide layer disappears. Also, overall resistance significantly increases and consequently, the current flow is greatly inhibited (refer to FIG. 5). In case of removing the supplied voltage, it returns to the state that allows ‘write’ through re-tunneling (refer to FIG. 6).

In case of reading the non-volatile memory device of the present invention, identification of a flowing current allows to achieve a read state when both electrodes are supplied with V_{read}, voltage of 0 to V_{TH}. Current flows on ON condition, more than on OFF condition at a voltage V_{read}.

### BRIEF DESCRIPTION OF THE DRAWINGS

FIG. 1 is a graph illustrating current-voltage characteristics corresponding to ‘write’, ‘delete’ and ‘read’ operation in the bistable memory device fabricated according to one embodiment of the present invention.

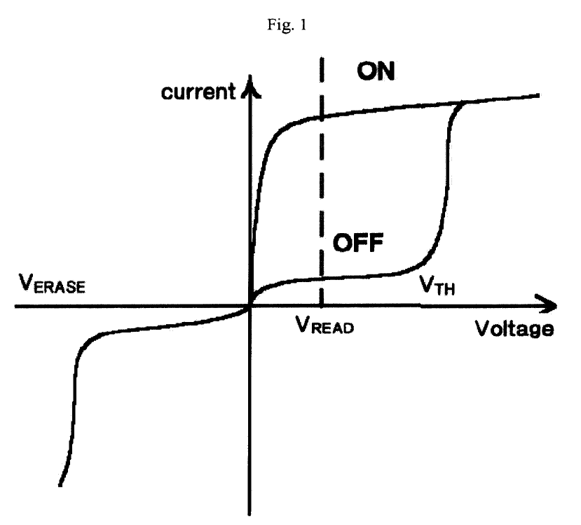

FIG. 2 is a schematic diagram of energy bands when voltage is not supplied to the bistable memory device fabricated according to one embodiment of the present invention.

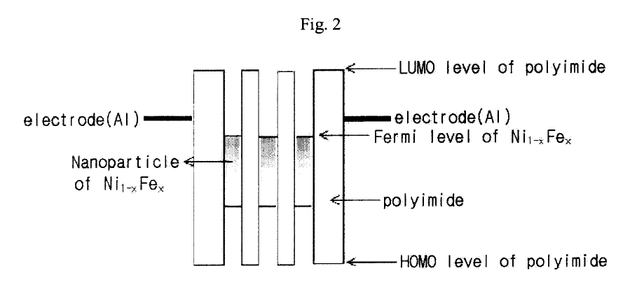

FIG. 3 is a schematic diagram of energy bands when voltage is supplied in the forward direction to the bistable memory device fabricated according to one embodiment of the present invention.

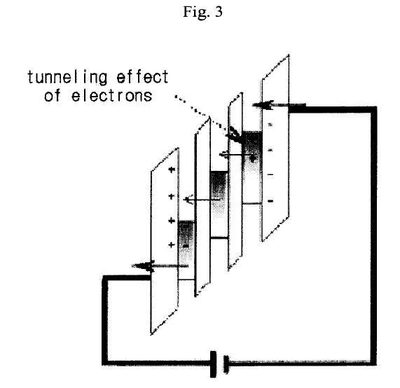

FIG. 4 is a schematic diagram of energy bands when the voltage supplied in the forward direction to the bistable memory device fabricated according to one embodiment of the present invention is removed.

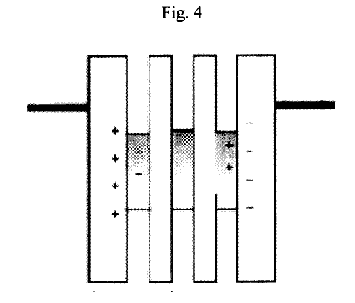

FIG. 5 is a schematic diagram of energy bands when voltage is supplied in the backward direction to the bistable memory device fabricated according to one embodiment of the present invention after removing voltage supplied in the forward direction.

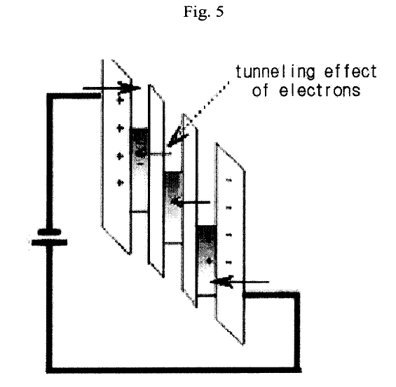

FIG. 6 is a schematic diagram of energy bands when the voltage supplied in the backward direction to the bistable memory device fabricated according to one embodiment of the present invention after removing voltage supplied in the forward direction is removed again.

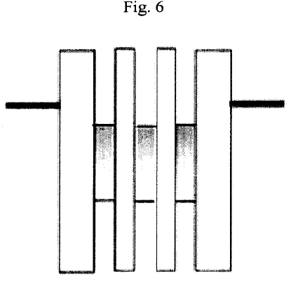

FIG. 7 is a plane-view TEM (Transmission Electron Microscopy) micrograph of Ni₁₋ₓFeₓ nano-crystallines embedded in the polyimide thin film formed on Si substrates.

FIG. 8 is an electron diffraction pattern image of Ni₁₋ₓFeₓ single layer of nano-crystallines embedded in the polyimide thin film formed on Si substrates.

FIG. 9 is a cross-sectional TEM image of Ni₁₋ₓFeₓ multiple layers of nano-crystallines embedded in the polyimide thin film formed on Si substrates.

FIG. 10 is a schematic diagram of a non-volatile bistable memory device using multi-layered Ni₁₋ₓFeₓ nano-crystalline arrays embedded into the polyimide thin film.

### EMBODIMENTS

Embodiments of the present invention will be described in more detail by accompanying drawings.

### Example 1

Precursor, polyamic acid of biphenyltetracaboxylic dianhydride-p-phenylenediamine (BPDA-PDA) (PI2610D, DuPont) type in a solvent of N-methyl-2-pyrrolidone (NMP) with 1:3 volume ratio was spin-coated on a silicon substrate. After removing remaining solvent with heating at 135° C. for 30 minutes, 5 nm of a Ni_{0.8}Fe_{0.2} layer was formed by sputtering on the resulting polyimide layer. Polyamic acid was again spin-coated thereon using the method described above and placed at room temperature for 2 hours. The remaining solvent was removed by heating the resulting PI/Ni_{0.8}Fe_{0.2}/PI/Si layer at 135° C. for 30 minutes and the polyamic acid was hardened to the polyimide by heating at 400° C. for 1 hours under 10⁻³ Pa.

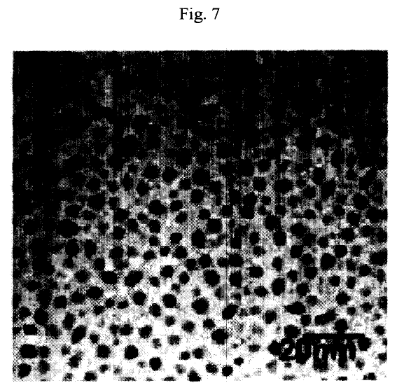

The Ni_{0.8}Fe_{0.2} nano-crystallines in the PI thin layer was observed using JEM 2010 JEOL Transmission Electron Microscope and represented by FIG. 7. According to FIG. 7, Ni₁₋ₓFeₓ nano-crystallines were formed dispersed in polyimide thin layer of which the size is equal to or less than 4-6 nm and the surface density is about 2×10¹² cm⁻².

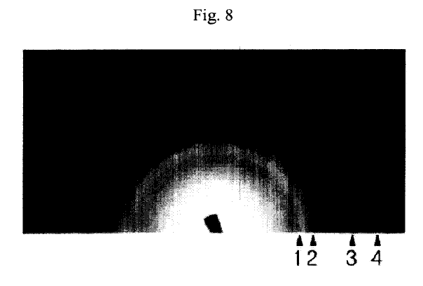

FIG. 8 is a selected area electron diffraction pattern image of Ni₁₋ₓFeₓ nano-crystallines embedded in the polyimide thin layer. It is found that the nano-crystallines have face-centered cubic structure and diffused rings occur due to the small size of the particles.

### Example 2

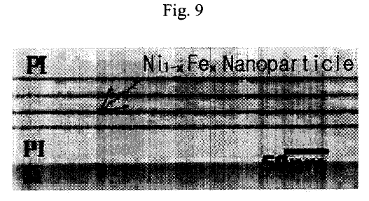

Precursor, polyamic acid of biphenyltetracaboxylic dianhydride-p-phenylenediamine (BPDA-PDA) (PI2610D, DuPont) type in a solvent of N-methyl-2-pyrrolidone (NMP) with 1:3 volume ratio was spin-coated on a silicon substrate. After removing a remaining solvent with heating at 135° C. for 30 minutes, 5 nm of Ni_{0.8}Fe_{0.2} layer was formed by sputtering on the resulting polyimide layer. The process was repeated 3 times and polyamic acid was again spin-coated on the resulting layer by the method described above and placed at room temperature for 2 hours. The remaining solvent was removed by heating the resulting PI/Ni_{0.8}Fe_{0.2}/PI/Si layer at 135° C. for 30 minutes, and the polyamic acid was hardened to the polyimide by heating at 400° C. for 1 hours under 10⁻³ Pa. Then, the cross-sectional TEM image of the Ni₁₋ₓFeₓ nano-particle multilayer formed in the PI layer on the Si substrate was observed using JEM 2010 JEOL Transmission Electron Microscope and represented by FIG. 9. According to FIG. 9, Ni₁₋ₓFeₓ nano-crystallines exist in the form of multilayer having one side size of 4-6 nm.

### Example 3

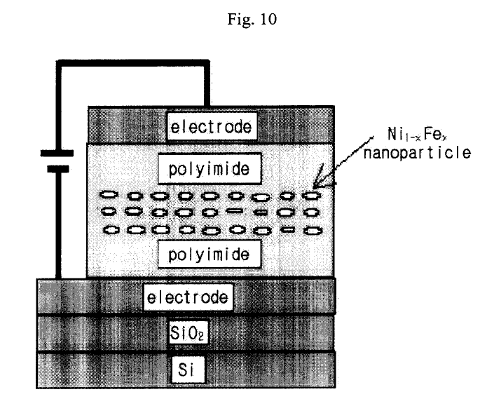

After depositing an Al electrode on a SiO₂-deposited silicon substrate, precursor polyamic acid of biphenyltetracaboxylic dianhydride-p-phenylenediamine (BPDA-PDA) (PI2610D, DuPont) type in solvent N-methyl-2-pyrrolidone (NMP) with 1:3 volume ratio was spin-coated on a the substrate. After removing a remaining solvent with heating at 135° C. for 30 minutes, 5 nm of the Ni_{0.8}Fe_{0.2} layer was formed by sputtering on the resulting polyimide layer. The spin-coating and sputtering process was repeated 2 times more, and polyamic acid was again spin-coated on the layer by the method described above and placed at room temperature for 2 hours. The remaining solvent was removed by heating the resulting PI/Ni_{0.8}Fe_{0.2}/PI/Ni_{0.8}Fe_{0.2}/PI/Ni_{0.8}Fe_{0.2}/PI/Al/SiO₂/Si layer at 135° C. for 30 minutes and the polyamic acid was hardened to polyimide by heating at 400° C. for 1 hours under 10⁻³ Pa. The non-volatile bistable memory device of the present invention having Al/PI/Ni_{0.8}Fe_{0.2}/PI/Ni_{0.8}Fe_{0.2}/PI/Ni_{0.8}Fe_{0.2}/PI/Al/SiO₂/Si structure was fabricated finally by again depositing an Al electrode on the layer (refer to FIG. 10).

### INDUSTRIAL APPLICABILITY

It is possible to fabricate nano-crystallines more simply than hitherto method according to the present invention. More particularly, it is possible to control size and density of nano-crystallines without the agglomeration of the crystallines since the crystallines, which have uniform distribution, are besieged to a polymer layer. Also, source and drain regions are unnecessary in the present invention, it can reduce the throughput time and the cost. Moreover, the present invention provides the non-volatile bistable memory device of high efficiency and low cost by using the nano-crystallines having chemical and electrical stability and it is very useful in the electronic information storage field.

What is claimed is:

1. A non-volatile bistable device comprising:
a semiconductor substrate;
an insulating layer formed on the semiconductor substrate;
a first electrode on the insulating layer;
a multilayered bistable complex composed of Ni₁₋ₓFeₓ nano-crystallines in a polymer thin film formed on the first electrode; and
a second electrode on the bistable complex, which is formed separated electrically by said polymer thin film.

2. The non-volatile bistable device according to claim 1, wherein the polymer thin film is a polyimide thin film.

3. The non-volatile bistable device according to claim 1 or 2, wherein the range of x in Ni₁₋ₓFeₓ is 0<x<0.5.

4. A fabrication method of a non-volatile bistable device comprising the steps of:
forming an insulating layer on a semiconductor substrate;
forming a first electrode layer on the insulating layer;
forming in multiple layers a bistable complex composed of Ni₁₋ₓFeₓ nanocrystallines in a polymer thin film on the first electrode; and
forming a second electrode layer on the bistable complex.

5. The fabrication method of a non-volatile bistable device according to claim 4, wherein the step of forming the bistable complex comprising:
a) spin-coating a polymer solution obtained by dissolving an acidic precursor containing a monomer of an insulating polymer into a solvent on the coated metal and removing the solvent from the coated acidic precursor;
b) coating Ni₁₋ₓFeₓ on the resulting polymer layer;
c) repeating a) and b) steps at least once; and
d) spin-coating a polymer solution obtained by dissolving an acidic precursor containing a monomer of an insulating polymer into a solvent and heating the polymer to effect cross-linking in the coated acidic precursor.

6. The fabrication method of a non-volatile bistable device according to claim 4 or claim 5, wherein the polymer thin film is a polyimide thin film.

7. The fabrication method of a non-volatile bistable device according to claim 4 or claim 5, wherein the acidic precursor containing a monomer of an insulating polymer is an acidic precursor including carboxyl group.

8. The fabrication method of a non-volatile bistable device according to claim 4 or claim 5, wherein the method for coating Ni₁₋ₓFeₓ is sputtering.

9. The fabrication method of a non-volatile bistable device according to claim 4 or claim 6, wherein the step of forming the bistable complex comprising:
1) forming a metal electrode on a semiconductor substrate on which an insulating layer is deposited;
2) spin-coating polyamic acid of biphenyltetracaboxylic dianhydride-p-phenylenediamine (BPDA-PDA) type using N-methyl-2-pyrrolidone (NMP) as a solvent and removing the solvent;
3) forming a Ni₁₋ₓFeₓ layer having a thickness of 1-30 nm on the resulting polyimide layer;
4) repeating 2) and 3) steps at least once and heating at 300-400° C. for about 1 hour to harden; and
5) forming a second electrode on the hardened polyimide layer.

10. The fabrication method of a non-volatile bistable device according to claim 9, wherein a volumetric mixture ratio of N-methyl-2-pyrrolidone (NMP): biphenyltetracaboxylic dianhydride-p-phenylenediamine (BPDA-PDA) is 1:3.
